(19) United States
(12) Patent Application Publication
(10) Pub. No.: US 2021/0102974 A1
(43) Pub. Date: Apr. 8, 2021

(54) HYBRID PROBE CARD FOR TESTING COMPONENT MOUNTED WAFER

(71) Applicant: TEPS CO., LTD., Hwaseong-si, Gyeonggi-do (KR)

(72) Inventors: Jaehoon PARK, Hwanseong-si, Gyeonggi-do (KR); Jaebok LEE, Hwanseong-si, Gyeonggi-do (KR); Yunchang IM, Hwanseong-si, Gyeonggi-do (KR)

(73) Assignee: TEPS CO., LTD., Hwaseong-si, Gyeonggi-do (KR)

(21) Appl. No.: 16/464,580

(22) PCT Filed: Jan. 4, 2018
(86) PCT No.: PCT/KR2018/000150

§ 371 Date: May 28, 2019

(30) Foreign Application Priority Data
Jan. 17, 2017 (KR) 10-2017-0007898

(51) Int. Cl. G01R 1/073; G01R 31/28

(52) U.S. Cl. CPC G01R 1/07342; G01R 31/2831

(57) ABSTRACT

Disclosed is a probe card including: first probes disposed above a first region and configured to contact with test electrodes in the first region to transfer electrical signals thereto; second probes disposed above a second region and configured to contact with test electrodes on a component mounted in the second region to transfer the electrical signals thereto; a first guide plate disposed to face a semiconductor wafer and formed with first probe holes into which one ends of the first and second probes are inserted; a second guide plate disposed on an upper portion of the first guide plate and formed with second probe holes into which the other ends of the first probes are inserted; and a third guide plate disposed on an upper portion of the first guide plate and formed with third probe holes into which the other ends of the second probes are inserted.

### CROSS-REFERENCE TO PRIOR APPLICATIONS

This application is a National Stage Patent Application of PCT International Patent Application No. PCT/KR2018/000150 filed on Jan. 4, 2018 under 35 U.S.C. § 371, which claims priority to Korean Patent Application No. 10-2017-0007898 filed on Jan. 17, 2017, which are all hereby incorporated by reference in their entirety.

### BACKGROUND

The present invention relates to a probe card, and more particularly, to a hybrid probe card for effectively testing a three-dimensional wafer on which components are mounted.

With the development of the information technology (IT) industry in recent years, semiconductor chips are widely used in various fields such as computers, mobile phones, displays, game machines, home appliances, automobiles, and the like. These semiconductor chips are subjected to a pre-inspection to determine a pass/fail by evaluating whether the chips operate normally at each stage of a manufacturing process until the semiconductor chips are packaged in the final stage and mounted on finished products.

Out of the semiconductor inspection stages, the inspection in a wafer state is performed by inspecting an electrical operation of each chip at a wafer level before dicing hundreds to thousands of semiconductor chips made on a semiconductor wafer into individual chips and proceeding to an assembly process, and the inspection in a wafer state enables cost reduction in subsequent packaging stages by prefiltering chip defects at the wafer level. A probe card is a device for the inspection in such a wafer state and electrically connects the wafer and main inspection equipment to transfer test signals from the main inspection equipment to pads on the wafer. Specifically, the probe card includes a plurality of probes in the form of a needle, and each of the plurality of probes comes into contact with the pad of a semiconductor device on the wafer so that the test signals from the main inspection equipment are applied to the wafer pad. At this point, it is preferable that the contact between the probe and the wafer pad be uniformly performed at a constant contact force at each contact point. As for the type of the probe needle, there may be several types including pogo-type needles, cantilever needles, and buckling-type needles such as cobra needles, and an appropriate type of probe needle is selected and used according to the characteristics of the wafer.

Meanwhile, conventionally, a two-dimensional wafer has been used as a semiconductor wafer to be tested through such a probe card, wherein in the two-dimensional wafer, pads, bumps, copper (Cu) pillars, and the like, which are electrodes to be tested on a wafer, are all located on the same plane.

FIG. 1 illustrates various types of conventional probe cards configured to perform tests on such a two-dimensional wafer. Specifically, FIG. 1A illustrates a structure in which a two-dimensional wafer is tested with a horizontal-type probe card using a cantilever-type probe, FIG. 1B illustrates a structure in which a two-dimensional wafer is tested with a micro electro mechanical systems (MEMS) probe card, FIG. 1C illustrates a structure in which a two-dimensional wafer is tested with a vertical-type probe card using a pogo-type probe, and FIG. 1D illustrates a structure in which a two-dimensional wafer is tested with a vertical-type probe card using a cobra-shaped buckling probe.

As shown in FIGS. 1A to 1D, in a conventional two-dimensional wafer 11, all electrodes 12 to be tested such as pads, bumps, Cu-pillars, and the like are positioned on the same plane, and thus, a conventional probe card configured to test the electrodes 12 is also designed and assembled such that lengths and heights (distances from electrode pads) of probes in the probe card are uniform to allow the probe to come into contact with the electrode pad at a constant contact force at each contact point during a test.

In recent years, with advances in semiconductor technology, so-called three-dimensional wafers, which are wafers in a form in which components are mounted, have been developed. In the conventional two-dimensional wafer, electrode pads of a wafer to be tested exist on the same plane on a wafer surface as described above, but, in the case of the three-dimensional wafer on which components are mounted, electrode pads are disposed not only on the wafer surface but also on the mounted components, and thus, heights between the electrode pads to be tested are different in one wafer.

However, all the conventional probe cards are designed for testing the two-dimensional wafer, and accordingly, the probe cards are designed and fabricated such that the lengths and heights of all of the probes in the probe card are uniform. Thus, such a probe card is capable of testing only the two-dimensional wafer in which all the electrode pads on the wafer are positioned on the same plane, and in order to test the above-described three-dimensional wafer, at least two probe cards each individually designed and fabricated according to the heights of the electrode pads on the wafer should be prepared inevitably, and when a test operation is actually performed, the test should be performed a plurality of times while alternately replacing the plurality of probe cards.

This leads to an increase in the time and cost required to fabricate the probe card, and ultimately, leads to an increase in the wafer test time and thus an increase in overall manufacturing costs of semiconductor devices.

### SUMMARY

An objective of the present invention is to solve the technical problems of the conventional probe card as described above by providing a hybrid probe card for effectively testing a three-dimensional wafer on which components are mounted.

More specifically, the objective of the present invention is to reduce the number of probe cards required for testing a three-dimensional wafer by allowing electrode pads on a wafer surface and electrode pads on mounted components to be simultaneously tested using one probe card for the three-dimensional wafer on which components are mounted.

It is another objective of the present invention to reduce the test time required for testing a three-dimensional wafer on which components are mounted and overall manufacturing costs of semiconductor devices.

According to an aspect of the present invention, there is provided a probe card configured to test a semiconductor wafer provided with a first region where a component is not mounted and a second region where a component is mounted, and the probe card includes a plurality of first probes disposed above the first region and come into contact with test electrodes in the first region to transfer electrical signals thereto, a plurality of second probes disposed above the second region and come into contact with test electrodes on the component mounted in the second region to transfer the electrical signals thereto, a first guide plate disposed to face the semiconductor wafer and formed with a plurality of probe holes into which one ends of the first and second probes are inserted, a second guide plate disposed on the first guide plate and formed with a plurality of probe holes into which the other ends of the first probes are inserted, and a third guide plate disposed on an upper portion the first guide plate and formed with a plurality of probe holes into which the other ends of the second probes are inserted, wherein a step having a height corresponding to a height of the component is formed in the first guide plate in a region in which the probe holes, into which one ends of the second probes are inserted, are formed such that a distance between the one ends of the first probes and the test electrodes in the first region is equal to a distance between the one ends of the second probes and the test electrodes on the component in the second region.

The probe card further includes a probe printed circuit board (PCB) formed with signal wirings configured to distribute the electrical signals and transfer the distributed electrical signals to the first and second probes, and a space transformer configured to redistribute the electrical signals from the signal wirings and transfer the redistributed electrical signals to the other end of each of the first and second probes, wherein a step is formed in the space transformer in a region facing the third guide plate such that a distance between the other ends of the first probes exposed from the second guide plate and corresponding electrical contacts on the space transformer is equal to a distance between the other ends of the second probes exposed from the third guide plate and the corresponding electrical contacts on the space transformer.

The first probe and the second probe may be any one of a pogo-type probe or a buckling-type probe.

The first probe and the second probe may be the same type of probe.

The first probe and the second probe may be different types of probes.

According to a probe card of the present invention, the number of probe cards required for testing a three-dimensional wafer can be reduced by allowing electrode pads on a wafer surface and electrode pads on mounted components to be simultaneously tested using one probe card for the three-dimensional wafer on which components are mounted. Furthermore, the test time required for testing the three-dimensional wafer and overall manufacturing costs of semiconductor devices can be reduced.

### BRIEF DESCRIPTION OF THE DRAWINGS

FIG. 1 shows cross-sectional views illustrating structures of various conventional probe cards configured to test a two-dimensional wafer.

FIG. 2 is a cross-sectional view illustrating a structure of a probe card according to a first embodiment of the present invention.

FIG. 3 is a cross-sectional view illustrating a structure of a probe card according to a second embodiment of the present invention.

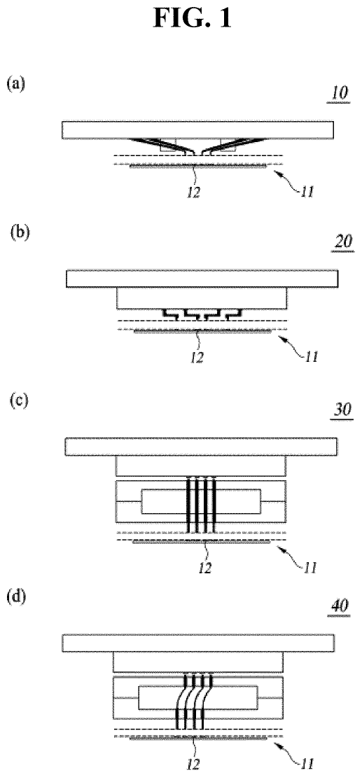

### DETAILED DESCRIPTION

Hereinafter, embodiments of the present invention will be described in detail to aid in an understanding the present invention. However, embodiments according to the present invention may be modified into various forms and, it should not be interpreted that the scope of the present invention is limited to the embodiments. The embodiments of the present invention are provided to more fully describe the present invention to those skilled in the art.

Further, it should be noted that sizes, shapes, and the like of components shown in the accompanying drawings, which are referred to in the following detailed description, may be exaggeratedly emphasized for clarity and convenience of explanation.

Further, terms which will be described below are those defined in consideration of functions in the present invention and thus may vary according to an intention of a user or an operator, or a practice. Therefore, such terms should be defined on the basis of contents throughout the present specification.

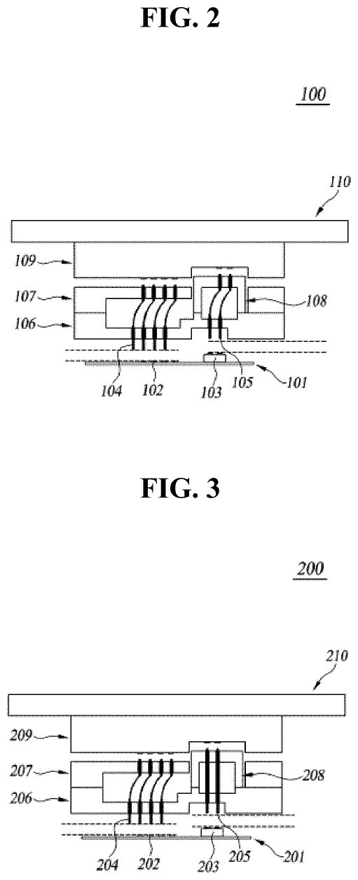

FIG. 2 illustrates a cross-sectional structure of a probe card 100 according to a first embodiment of the present invention.

A first region R1 in which components are not mounted and a second region R2 in which components 103 are mounted are formed in a semiconductor wafer 101 which is tested by the probe card 100 according to the first embodiment of the present invention. That is, since the region where the components are not mounted and the region where the components are mounted are mixed on one wafer, a structure of a three-dimensional wafer in which contacted electrode pads to be tested are not on the same plane is formed. As described above, conventionally, one probe card for a ‘wafer test’ (test of electrode pads on a wafer surface) and one probe card for a ‘component test’ (test of electrode pads on mounted components) are required to test the three-dimensional wafer. However, the probe card according to the present invention may simultaneously perform the wafer test and the component test using one probe card on the three-dimensional wafer. Hereinafter, a structure of the probe card 100 according to the first embodiment of the present invention will be described in detail.

The probe card 100 according to the first embodiment of the present invention includes a plurality of probes 104 and 105 configured to come into contact with a test body and transfer electrical signals thereto and a probe printed circuit board (PCB) 110 on which signal wirings are formed to distribute the electrical signals and transfer the distributed electrical signals to the plurality of probes 104 and 105. A space transformer 109 configured to redistribute the electrical signals from the signal wirings on the probe PCB 100 and transfer the redistributed electrical signal to each of the plurality of probes 104 and 105 is installed below the probe PCB 110. A probe assembly is installed below the space transformer 109, and the probe assembly is configured to perform electrical tests by simultaneously coming into contact with the test body on a three-dimensional wafer 101, that is, electrode pads 102 on a wafer surface, and electrode pads on the components 103 mounted on the wafer. The probe assembly is macroscopically and functionally composed of a first probe assembly configured to come into contact with the electrode pads 102 on the wafer surface to test the electrode pads 102 and a second probe assembly configured to come into contact with the electrode pads on the components 103 mounted on the wafer to test the electrode pads.

The basic configuration of the probe assembly is formed such that a plurality of probes are vertically and movably supported by two guide plates disposed on upper and lower sides. First, a first guide plate 106 is disposed in a shape facing the semiconductor wafer 101. The first guide plate 106 is formed with probe holes into which one ends of the plurality of probes (first probes) 104 may be inserted, respectively, in the region R1 corresponding to the electrode pads 102 on the wafer surface, and formed with probe holes into which one ends of another plurality of probes (second probes) 105 may be inserted, respectively, in the region R2 corresponding to the electrode pads on the mounted components 103. For the type of the first and second probes 104 and 105, a buckling-type probe such as a cobra-type probe, or a pogo-type probe may be used, and the first embodiment shown has a configuration in which both the first probes 104 and the second probes 105 use the same type of the buckling-type probe.

Meanwhile, a second guide plate 107 is disposed on the first guide plate 106 in parallel with the first guide plate 106, and a plurality of probe holes into which the other ends of the first probes 104 may be inserted are formed in the second guide plate 107 in the region corresponding to the region R1.

An opening is formed in the region of the second guide plate 107 corresponding to the region R2 on the wafer in which the components 103 are mounted, and a third guide plate 108, which will be described below, is installed through the opening. That is, the third guide plate 108 is inserted through the opening of the second guide plate 107 and assembled and disposed on an upper portion of the first guide plate 106 at a position corresponding to the region R2 where the components are mounted, and a plurality of probe holes, into which the other ends of the second probes 105 to be brought into contact with the electrode pads of the components 103 are inserted, are formed in the third guide plate 108.

Through the above-described configuration, the first guide plate 106, the second guide plate 107, and the first probes 104 inserted into the probe holes of the first and second guide plates, which are all positioned in the region R1, are functionally configured as one probe assembly for performing the wafer test. Further, the first guide plate 106, the third guide plate 108, and the second probes 105 inserted into the probe holes of the first and third guide plates, which are all positioned on the region R2, are functionally configured as another probe assembly for performing the component test.

Meanwhile, as shown in FIG. 2, a step having a height corresponding to a height of the component 103 mounted on the wafer is formed inwardly (in a direction away from the wafer) in the first guide plate 106 in the region where the probe holes into which one ends of the second probes 105 are inserted are formed. Such a step allows a distance between one end of the first probe 104 exposed below the first guide plate 106 and the electrode pad 102 on the wafer surface in the position of the region R1 to be maintained equal to a distance between one end of the second probe 105 exposed below the first guide plate 106 and the electrode pad on the component 103 in the position of the region R2.

Further, in a similar manner, a step having a height corresponding to a height at which the third guide plate 108 is exposed upward from the opening of the second guide plate 107 is also formed inwardly (in a direction away from the wafer) in the space transformer 109 in a region facing the third guide plate 108, that is, in a region facing the region where the probe holes into which the other ends of the second probes 105 are inserted are formed. Such a step allows a distance between the other ends of the first probes exposed from the second guide plate and corresponding electrical contact points on the space transformer to be maintained equal to a distance between the other ends of the second probes exposed from the third guide plate and corresponding electrical contact points on the space transformer even in an electrical contact region between the space transformer 109 and the first and second probes 104 and 105.

As described above, in the probe card according to the first embodiment of the present invention, two probe assemblies corresponding to the region R1, in which the components are not mounted, and the region R2, in which the components are mounted, of the three-dimensional wafer are disposed in a functionally combined form, and appropriate steps are provided in the first guide plate 106 of the probe assembly and the space transformer 109, respectively, in the regions thereof corresponding to the region R2 where the components are mounted, thereby allowing the first and second probes 104 and 105 to be simultaneously and uniformly brought into contact with the electrode pads 102 on the wafer surface and the electrode pads on the mounted components 103 with a constant contact force in the regions R1 and R2, that is, in the test regions, when the first and second probes 104 and 105 are lowered and the test is performed. Finally, by using the probe card according to the present invention, the wafer test and the component test in the three-dimensional wafer on which the components are mounted may be performed simultaneously with only one probe card, and as a result, it may be possible to reduce manufacturing costs of the semiconductor due to the reduction in the number of probe cards required for the three-dimensional wafer test, and simultaneously, the overall test time may be shortened.

FIG. 3 illustrates a cross-sectional structure of a probe card 200 according to a second embodiment of the present invention.

The probe card 200 according to the second embodiment of the present invention has substantially the same structure as that of the probe card 100 according to the first embodiment except that the probe card 200 includes a first probe 204 and a second probe 205 in different types of probes.

Specifically, as shown in the drawing, in the second embodiment, a buckling-type probe is used as the first probe 204, and a pogo-type probe is used as the second probe 205, respectively. Except that two different types of probes are used for the first and second probes 204 and 205, the characteristic configuration in which two probe assemblies corresponding to a region R1, in which components are not mounted, and a region R2, in which the components are mounted, are disposed in a functionally combined form, and appropriate steps are provided in a first guide plate 206 of a probe assembly and a space transformer 209, respectively, in regions thereof corresponding to the region R2 where the components are mounted, is the same as that of the probe card 100 according to the first embodiment described above. Accordingly, a wafer test and a component test on a three-dimensional wafer on which the components are mounted may be performed simultaneously with only one probe card even in the probe card 200 according to the second embodiment, thereby obtaining the effect of reducing the number of probe cards required for the three-dimensional wafer test and reducing the test time in the same manner.

While the present invention has been described above with reference to the exemplary embodiments, it should be understood that the present invention is not limited to the disclosed exemplary embodiments. For example, in the above-described embodiments, the first probe for the wafer test and the second probe for the component test have been described using any one of a buckling-type probe such as a cobra-type probe, or a pogo-type probe, but the type of the probe is not necessarily limited thereto. Further, in the above-described first embodiment, an example of using a buckling-type probe as the first and second probes has been described as an example of using the same type of probe as the first and second probes, but it is, of course, possible to use a configuration in which a pogo-type probe is used as both the first and second probes. Also, even in the second embodiment in which different types of probes are used for the first and second probes, a modification is also possible in which the first probe is configured by a pogo-type probe and the second probe is configured by a buckling-type probe unlike the second embodiment described above.

Although specific terms have been used to describe the present invention, the specific terms are used in a generic and descriptive sense only and not for purposes of limitation and should be understood accordingly. Accordingly, it will be understood by those of ordinary skill in the art that various changes in form and details may be made without departing from the spirit and scope of the present invention as set forth in the following claims. The scope of the following claims is to be accorded the broadest interpretation so as to encompass all such modifications and equivalent structures and functions.

1. A probe card, which is configured to test a semiconductor wafer provided with a first region where a component is not mounted and a second region where a component is mounted, the probe card comprising:
a plurality of first probes disposed above the first region and configured to come into contact with test electrodes in the first region to transfer electrical signals thereto;
a plurality of second probes disposed above the second region and configured to come into contact with test electrodes on the component mounted in the second region to transfer the electrical signals thereto;
a first guide plate disposed to face the semiconductor wafer and formed with a plurality of probe holes into which one ends of the first and second probes are inserted;
a second guide plate disposed on an upper portion of the first guide plate and formed with a plurality of probe holes into which the other ends of the first probes are inserted; and
a third guide plate disposed on an upper portion of the first guide plate and formed with a plurality of probe holes into which the other ends of the second probes are inserted,
wherein a step having a height corresponding to a height of the component is formed in the first guide plate in a region in which the probe holes, into which one ends of the second probes are inserted, are formed such that a distance between the one ends of the first probes and the test electrodes in the first region is equal to a distance between the one ends of the second probes and the test electrodes on the component in the second region.

2. The probe card of claim 1, further comprising a probe printed circuit board (PCB) formed with signal wirings configured to distribute the electrical signals and transfer the distributed electrical signals to the first and second probes, and a space transformer configured to redistribute the electrical signals from the signal wirings on the probe PCB and transfer the redistributed electrical signals to the other ends of the first and second probes respectively, wherein a step is formed in the space transformer in a region facing the third guide plate such that a distance between the other ends of the first probes exposed from the second guide plate and corresponding electrical contacts on the space transformer is equal to a distance between the other ends of the second probes exposed from the third guide plate and the corresponding electrical contacts on the space transformer.

3. The probe card of claim 1 or 2, wherein the first probe and the second probe are any one of a pogo-type probe or a buckling-type probe.

4. The probe card of claim 3, wherein the first probe and the second probe are the same type of probe.

5. The probe card of claim 3, wherein the first probe and the second probe are different types of probes.
